(19) United States
(12) Patent Application Publication
(10) Pub. No.: US 2024/0297165 A1
(43) Pub. Date: Sep. 5, 2024

(54) DOUBLE-SIDED REDISTRIBUTION LAYER (RDL) SUBSTRATE WITH DOUBLE-SIDED PILLARS FOR DEVICE INTEGRATION

(71) Applicant: QUALCOMM Incorporated, San Diego, CA (US)

(72) Inventors: Changhan Hobie YUN, San Diego, CA (US); Paragkumar Ajaybhai THADESAR, San Diego, CA (US); Sameer Sunil VADHAVKAR, San Diego, CA (US); Youngju PARK, Incheon (KR); Doosoub SHIN, Incheon (KR)

(21) Appl. No.: 18/177,404

(22) Filed: Mar. 2, 2023

(51) Int. Cl. H01L 25/18; H01L 23/00; H01L 23/498; H01L 25/00; H01L 27/01

(52) U.S. Cl. CPC H01L 25/18; H01L 23/49822; H01L 23/49827; H01L 24/14; H01L 24/16; H01L 24/17; H01L 24/32; H01L 24/73; H01L 24/81; H01L 24/92; H01L 25/50; H01L 27/01; H01L 23/49811; H01L 2224/14181; H01L 2224/16145; H01L 2224/16227; H01L 2224/17181; H01L 2224/32145; H01L 2224/73204; H01L 2224/81005; H01L 2224/81815; H01L 2224/92125

(57) ABSTRACT

A device is described, including a redistribution layer (RDL) substrate. The device also includes a passive component in the RDL substrate proximate a first surface of the RDL substrate. The device further includes a first die coupled to a second surface of the RDL substrate, opposite the first surface of the RDL substrate, through at least a first pair of conductive pillars. The device also includes a laminate substrate coupled to the first surface of the RDL substrate through at least a second pair of conductive pillars.

### BACKGROUND

### Field

Aspects of the present disclosure relate to semiconductor devices and, more particularly, to a wafer-level, double-sided redistribution layer (RDL) substrate with double-sided pillars for device integration.

### Background

Wireless communications devices incorporate radio frequency (RF) modules that facilitate the communication and features users expect. As wireless systems become more prevalent and include more capabilities, the chips become more complex. Fifth generation (5G) new radio (NR) and sixth generation (6G) wireless communications devices incorporate the latest generation of electronic dies that are packed into smaller modules with smaller interconnections. Design challenges include integrating passive devices and active devices to implement RF front-end (RFFE) modules.

An RFFE module may be implemented by integrating RF filters, active devices, and surface-mount technology (SMT) devices on a laminate substrate. These RF filters, active devices, and SMT devices are conventionally arranged in a side-by-side on package configuration supported by a laminate substrate. Unfortunately, these conventional side-by-side on package laminate configurations are subjected to decreasing XY size and Z height limitations due to the reduced form factor of future applications. That is, the XY size and Z height dimensions of conventional side-by-side on package laminate configurations exceed the form factor of future RFFE module applications. An RFFE implementation that meets reduced XY size and Z height dimensions specified by the form factor of future RFFE module applications is desired.

### SUMMARY

A device is described, including a redistribution layer (RDL) substrate. The device also includes a passive component in the RDL substrate proximate a first surface of the RDL substrate. The device further includes a first die coupled to a second surface of the RDL substrate, opposite the first surface of the RDL substrate, through at least a first pair of conductive pillars. The device also includes a laminate substrate coupled to the first surface of the RDL substrate through at least a second pair of conductive pillars.

A method for fabricating a radio frequency (RF) device is described. The method includes forming a redistribution layer (RDL) substrate on a carrier glass substrate, the RDL substrate including a passive component and a first RDL in an interlayer dielectric (ILD) layer of the RDL substrate. The method also includes forming a first pair of conductive pillars coupled to the passive component and the first RDL of the RDL substrate proximate a first surface of the RDL substrate. The method further includes coupling a first die to the first surface of the RDL substrate, opposite a second surface of the RDL substrate, through the first pair of conductive pillars. The method also includes removing the carrier glass substrate from the second surface of the RDL substrate. The method further includes forming a second pair of conductive pillars coupled to the passive component and the first RDL of the RDL substrate proximate the second surface of the RDL substrate. The method also includes coupling a laminate substrate to the second surface of the RDL substrate through the second pair of conductive pillars.

A device is described, including a redistribution layer (RDL) substrate, having a passive component and a first RDL in an interlayer dielectric (ILD) layer of the RDL substrate. The device also includes a first die coupled to a first surface of the RDL substrate, opposite a second surface of the RDL substrate. The device further includes a first molding compound (MC) layer on the first surface of the RDL substrate and the first die. The device also includes a second die coupled to the first RDL of the RDL substrate proximate the second surface of the RDL substrate. The device further includes a second MC layer on the second surface of the RDL substrate and the second die.

A method for fabricating a radio frequency (RF) device is described. The method includes forming a redistribution layer (RDL) substrate on a carrier glass substrate, the RDL substrate including a passive component and a first RDL in an interlayer dielectric (ILD) layer of the RDL substrate. The method also includes coupling a first die to a first surface of the RDL substrate, opposite a second surface of the RDL substrate. The method further includes depositing a first molding compound (MC) layer on the first surface of the RDL substrate and the first die. The method also includes removing the carrier glass substrate from the second surface of the RDL substrate. The method further includes coupling a second die to the first RDL of the RDL substrate proximate the second surface of the RDL substrate. The method also includes depositing a second MC layer on the second surface of the RDL substrate and the second die.

This has outlined, rather broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for carrying out the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 is a schematic diagram of a radio frequency front-end (RFFE) module employing active and passive devices.

FIG. 2 is a schematic diagram of a radio frequency integrated circuit (RFIC) chip having a wireless local area network (WLAN) module and a radio frequency front-end (RFFE) module for a chipset.

FIG. 3 is a block diagram illustrating a cross-sectional view of a radio frequency front-end (RFFE) module including a semiconductor die and an integrated passive device (IPD) filter die, in accordance with aspects of the present disclosure.

FIG. 4 is a block diagram illustrating a radio frequency (RF) device including wafer-level, double-sided redistribution layer (RDL) substrates having doubled-sided conductive pillars for device integration, according to aspects of the present disclosure.

FIGS. 5A-5B are schematic diagrams further illustrating the radio frequency (RF) device of FIG. 4, according to aspects of the present disclosure.

FIGS. 5C-5D are schematic diagrams further illustrating the radio frequency (RF) device of FIGS. 5A-5B having planar inductors, according to further aspects of the present disclosure.

FIGS. 6A and 6B are block diagrams further illustrating the radio frequency (RF) device of FIG. 4, according to aspects of the present disclosure.

FIGS. 7A-7B are block diagrams illustrating various options to assemble a redistribution layer (RDL) substrate and a die to form radio frequency front-end (RFFE) modules, according to aspects of the present disclosure.

FIGS. 8A-8C are block diagrams further illustrating variations of the radio frequency (RF) device of FIG. 4, according to aspects of the present disclosure.

FIGS. 9A-9B are block diagrams illustrating a radio frequency (RF) device including a redistribution layer (RDL) substrate, according to aspects of the present disclosure.

FIGS. 10A-10D are block diagrams illustrating a process of fabricating a radio frequency (RF) device including a redistribution layer (RDL) substrate, having double-sided conductive pillars, according to aspects of the present disclosure.

FIG. 11 is a process flow diagram illustrating a method for fabricating a radio frequency front-end (RFFE) module including a redistribution layer (RDL) substrate, according to aspects of the present disclosure.

FIG. 12 is a block diagram showing an exemplary wireless communications system in which a configuration of the present disclosure may be advantageously employed.

FIG. 13 is a block diagram illustrating a design workstation used for circuit, layout, and logic design of a semiconductor component according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

As described herein, the use of the term “and/or” is intended to represent an “inclusive OR,” and the use of the term “or” is intended to represent an “exclusive OR.” As described herein, the term “exemplary” used throughout this description means “serving as an example, instance, or illustration,” and should not necessarily be construed as preferred or advantageous over other exemplary configurations. As described herein, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described herein, the term “proximate” used throughout this description means “adjacent, very near, next to, or close to.” As described herein, the term “on” used throughout this description means “directly on” in some configurations, and “indirectly on” in other configurations.

Wireless communications devices incorporate radio frequency (RF) modules that facilitate the communication and features users expect. As wireless systems become more prevalent and include more capabilities, the chips become more complex. For example, mobile RF chips (e.g., mobile RF transceivers) have migrated to a deep sub-micron process node due to cost and power consumption considerations. Designing mobile RF transceivers is complicated by added circuit functions for supporting communications enhancements, such as fifth generation (5G) new radio (NR) communications systems. In particular, 5G NR wireless communications devices incorporate the latest generation of electronic dies that are packed into smaller modules with smaller interconnections. Design challenges include integrating passive devices and active devices to implement RF front-end modules (FEMs).

RF filters in mobile RF transceivers may include high performance capacitor and inductor components. For example, RF filters use various types of passive devices, such as integrated capacitors and integrated inductors. Integrated capacitors may include metal-oxide-semiconductor (MOS) capacitors, p-n junction capacitors, metal-insulator-metal MIM) capacitors, poly-to-poly capacitors, metal-oxide-metal (MOM) capacitors, and other like capacitor structures. Capacitors are generally passive elements used in integrated circuits for storing an electrical charge. For example, parallel plate capacitors are often made using plates or structures that are conductive with an insulating material between the plates.

An inductor is an example of an electrical device used to temporarily store energy in a magnetic field within a wire coil according to an inductance value. This inductance value provides a measure of the ratio of voltage to the rate of change of current passing through the inductor. When the current flowing through an inductor changes, energy is temporarily stored in a magnetic field in the coil. In addition to their magnetic field storing capability, inductors are often used in alternating current (AC) electronic equipment, such as radio equipment. For example, the design of mobile RF transceivers includes the use of inductors with improved inductance density while reducing magnetic loss at millimeter wave (mmW) frequencies (e.g., frequency range two (FR2)).

A radio frequency front-end (RFFE) module may include a 5G broadband FR2 filter including MIM capacitors and inductors. In practice, an RFFE module may be implemented by integrating RF filters, active devices, and surface-mount technology (SMT) devices on a laminate substrate. These RF filters, active devices, and SMT devices are conventionally arranged in a side-by-side on package configuration supported by a laminate substrate. Unfortunately, this conventional side-by-side on package laminate configuration is subjected to decreasing XY size and Z height limitations due to the reduced form factor of future RF applications. That is, the XY size and Z height dimensions of conventional side-by-side on package laminate configurations exceed the form factor of future RFFE module applications. An RFFE implementation that meets reduced XY size and Z height dimensions specified by the form factor of future RFFE module applications is desired.

Various aspects of the disclosure provide a wafer-level, double-sided redistribution layer (RDL) substrate having double-sided conductive pillars for device integration. The process flow for fabrication of the RDL substrate may include wafer-level processes, such as front-end-of-line (FEOL) processes, middle-of-line (MOL) processes, and back-end-of-line (BEOL) processes. It will be understood that the term “layer” includes film and is not construed as indicating a vertical or horizontal thickness unless otherwise stated. As described, the term “substrate” may refer to a substrate of a diced wafer or may refer to a substrate of a wafer that is not diced. Similarly, the terms chip and die may be used interchangeably.

As described, the back-end-of-line (BEOL) interconnect layers may refer to the conductive interconnect layers (e.g., a first interconnect layer (M1) or metal one M1, metal two (M2), metal three (M3), metal four (M4), etc.) for electrically coupling to front-end-of-line (FEOL) active devices of an integrated circuit. The various BEOL interconnect layers are formed at corresponding BEOL interconnect layers, in which lower BEOL interconnect layers use thinner metal layers relative to upper BEOL interconnect levels. The BEOL interconnect layers may electrically couple to middle-of-line (MOL) interconnect layers, for example, to connect M1 to an oxide diffusion (OD) layer of an integrated circuit. The MOL interconnect layer may include a zero-interconnect layer (M0) for connecting M1 to an active device layer of an integrated circuit. A BEOL first via (V2) may connect M2 to M3 or others of the BEOL interconnect layers. The BEOL vias may also provide a via pad (VP) to support package (or device) interconnects, such as package balls.

According to aspects of the present disclosure, an RF device includes a redistribution layer (RDL) substrate. In addition, the RF device includes a passive component in the RDL substrate proximate a first surface of the RDL substrate. In some aspects of the present disclosure, the RF device includes a first die coupled to a second surface of the RDL substrate, opposite the first surface of the RDL substrate. In these aspects of the present disclosure, the first die is coupled to the second surface of the RDL substrate by a first pair of conductive pillars. Additionally, a laminate substrate is coupled to the first surface of the RDL substrate through at least a second pair of conductive pillars. In some aspects of the present disclosure, the RF device includes a second die coupled to the passive component, opposite the first die. In a multi-die configuration, the RF device includes a third die coupled to the passive component, opposite the first die and proximate the second die. In some aspects of the present disclosure, the first die, second die, and the third die may provide active components of an antenna module, such as an RF switch.

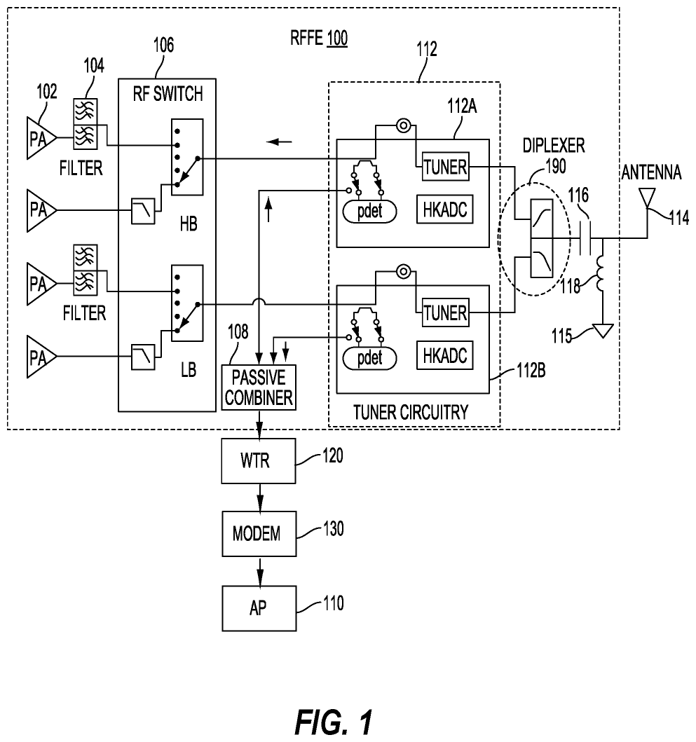

FIG. 1 is a schematic diagram of a radio frequency front-end (RFFE) module 100 employing a double-sided redistribution layer (RDL) substrate having double-sided conductive pillars for device integration, according to aspects of the present disclosure. The RFFE module 100 includes power amplifiers 102, duplexer/filters 104, and a radio frequency (RF) switch module 106. The power amplifiers 102 amplify signal(s) to a certain power level for transmission. The duplexer/filters 104 filter the input/output signals according to a variety of different parameters, including frequency, insertion loss, rejection, or other like parameters. In addition, the RF switch module 106 may select certain portions of the input signals to pass on to the rest of the RFFE module 100.

The radio frequency front-end (RFFE) module 100 also includes tuner circuitry 112 (e.g., first tuner circuitry 112A and second tuner circuitry 112B), the diplexer 190, a capacitor 116, an inductor 118, a ground terminal 115, and an antenna 114. The tuner circuitry 112 (e.g., the first tuner circuitry 112A and the second tuner circuitry 112B) includes components such as a tuner, a portable data entry terminal (PDET), and a housekeeping analog-to-digital converter (HKADC). The tuner circuitry 112 may perform impedance tuning (e.g., a voltage standing wave ratio (VSWR) optimization) for the antenna 114. The RFFE module 100 also includes a passive combiner 108 coupled to a wireless transceiver (WTR) 120. The passive combiner 108 combines the detected power from the first tuner circuitry 112A and the second tuner circuitry 112B. The wireless transceiver 120 processes the information from the passive combiner 108 and provides this information to a modem 130 (e.g., a mobile station modem (MSM)). The modem 130 provides a digital signal to an application processor (AP) 140.

As shown in FIG. 1, the diplexer 190 is between the tuner component of the tuner circuitry 112 and the capacitor 116, the inductor 118, and the antenna 114. The diplexer 190 may be placed between the antenna 114 and the tuner circuitry 112 to provide high system performance from the radio frequency front-end (RFFE) module 100 to a chipset including the wireless transceiver 120, the modem 130, and the application processor 110. The diplexer 190 also performs frequency domain multiplexing on both high band frequencies and low band frequencies. After the diplexer 190 performs its frequency multiplexing functions on the input signals, the output of the diplexer 190 is fed to an optional inductor-capacitor (LC) network including the capacitor 116 and the inductor 118. The LC network may provide extra impedance matching components for the antenna 114, when desired. Then, a signal with the particular frequency is transmitted or received by the antenna 114. Although a single capacitor and inductor are shown, multiple components are also contemplated.

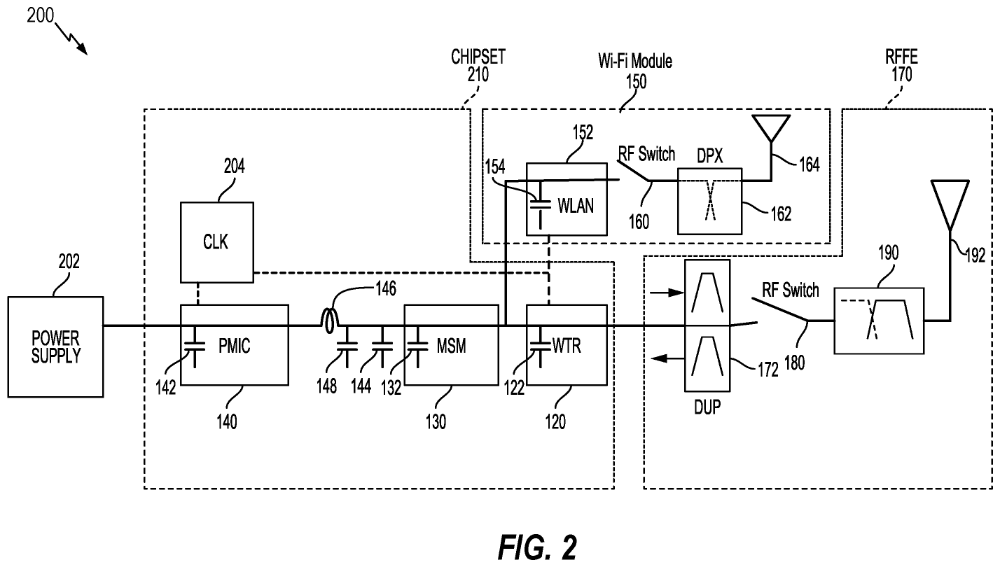

FIG. 2 is a schematic diagram of a radio frequency integrated circuit (RFIC) chip 200, having a wireless local area network (WLAN) (e.g., Wi-Fi) module 150 and a radio frequency front-end (RFFE) module 170 for a chipset 210. The Wi-Fi module 150 includes a first diplexer 162 communicably coupling an antenna 164 to a WLAN module 152. A first RF switch 160 communicably couples the first diplexer 162 to the WLAN module 152. The RFFE module 170 includes a second diplexer 190 communicably coupling an antenna 192 to a wireless transceiver (WTR) 120 through a duplexer 172. A second RF switch 180 communicably couples the second diplexer 190 to the duplexer 172.

The WTR 120 and the WLAN module 152 of the Wi-Fi module 150 are coupled to a modem (mobile station modem (MSM), e.g., baseband modem) 130 that is powered by a power supply 202 through a power management integrated circuit (PMIC) 140. The chipset 210 also includes capacitors 144 and 148, as well as an inductor(s) 146 to provide signal integrity. The PMIC 140, the modem 130, the WTR 120, and the WLAN module 152 each include capacitors (e.g., 142, 132, 122, and 154) and operate according to a clock 204. In addition, the inductor 146 couples the modem 130 to the PMIC 140. The geometry and arrangement of the various inductor and capacitor components in the RFIC) chip 200 may reduce the electromagnetic coupling between the components.

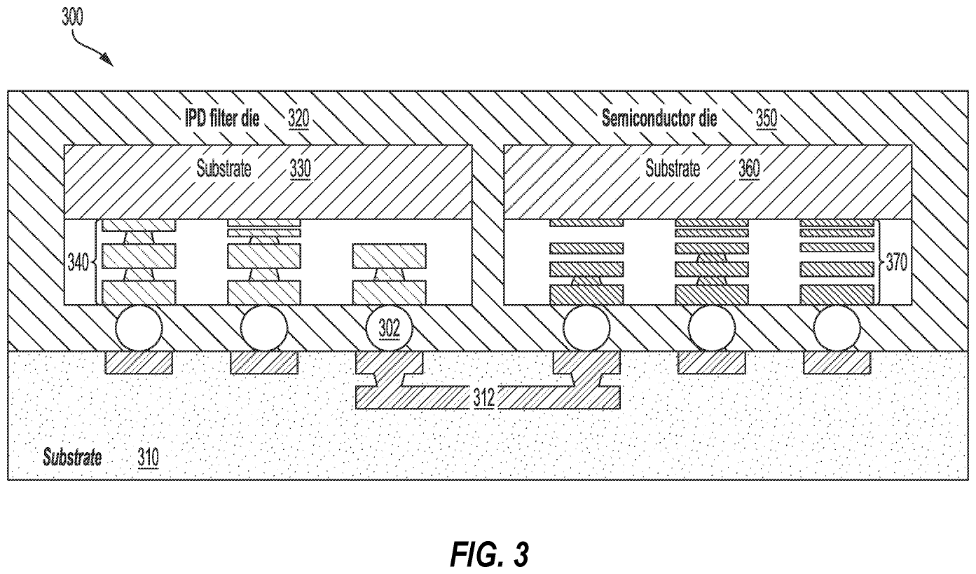

The WTR 120 of the wireless device generally includes a mobile RF transceiver to transmit and receive data for two-way communications. The WTR 120 and the RFFE module 170 may be implemented using high performance complementary metal oxide semiconductor (CMOS) RF switch technologies to implement switch transistors of the first RF switch 160 and the second RF switch 180. The RFFE module 170 may rely on these high performance CMOS RF switch technologies to implement an active die for successful operation. In practice, the active die used to implement the CMOS RF switch technology may involve integration with a passive RF filter to implement an antenna module, for example, as shown in FIG. 3.

FIG. 3 is a block diagram illustrating a cross-sectional view of a radio frequency front-end (RFFE) module 300 including a semiconductor die 350 and an integrated passive device (IPD) filter die 320, in accordance with aspects of the present disclosure. In this example, the RFFE module 300 includes the semiconductor die 350 and the IPD filter die 320 supported by a package substrate 310 (e.g., a laminate substrate). The semiconductor die 350 may be an active die having a semiconductor substrate 360 (e.g., an active silicon substrate) coupled to package balls 302 through back-end-of-line (BEOL) layers 370. The BEOL layers 370 include multiple BEOL metallization layers (M1, M2, M3, . . . , Mn) on the semiconductor substrate 360 (e.g., a diced silicon wafer). A redistribution layer 312 is coupled to the package balls 302.

The IPD filter die 320 includes a substrate 330 (e.g., a passive substrate) coupled to the package balls 302 through back-end-of-line (BEOL) layers 340. The redistribution layer 312 is coupled to the IPD filter die 320 through the package balls 302. In some aspects of the present disclosure, the substrate 330 is composed of glass, and the IPD filter die 320 is a glass-substrate integrated passive device (GIPD) filter die.

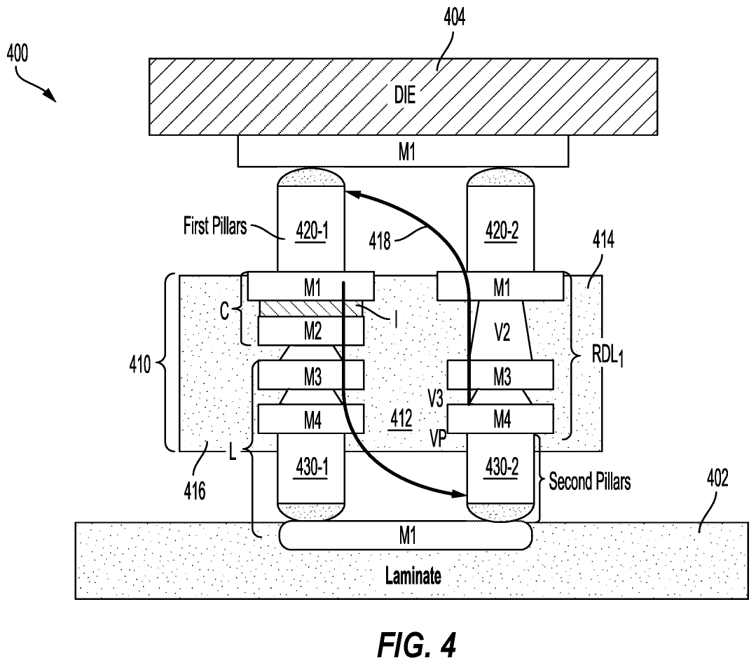

In practice, the RFFE module 300 integrates the IPD filter die 320, the semiconductor die 350, and surface-mount technology (SMT) devices on the package substrate 310 (e.g., laminate). The IPD filter die 320, the semiconductor die 350, and the SMT devices (not shown) are arranged in a side-by-side on package configuration supported by a package substrate 310. Unfortunately, this side-by-side on package substrate configuration is subjected to decreasing XY size and Z height limitations due to the reduced form factor of future RF applications. That is, the XY size and Z height dimensions of conventional side-by-side on package laminate configurations exceed the form factor of future RFFE module applications. An RFFE implementation that meets reduced XY size and Z height dimensions specified by the form factor of future RFFE module applications is shown, for example, in FIG. 4.

FIG. 4 is a block diagram illustrating a radio frequency (RF) device 400 including wafer-level, double-sided redistribution layer (RDL) substrates having double-sided conductive pillars for device integration, according to aspects of the present disclosure. Representatively, the RF device 400 includes an RDL substrate 410 composed of interlayer dielectric (ILD) layers 412 formed of, for example, polyimide. In some aspects of the present disclosure, the ILD layers 412 include a metal-insulator-metal (MIM) capacitor C and a 3D inductor L formed from back-end-of-line (BEOL) metallization layers M1, M2, M3, and M4 and BEOL vias V2, V3, and VP. The ILD layers 412 also include a first redistribution layer (RDL₁) to complete the RDL substrate 410.

In this example, the MIM capacitor C is formed using plates of the M1 and M2 metallization layers, below the metallization layer M3 using an insulation layer (I) that is not available during fabrication of organic laminate substrates such as silicon nitride (SiN) or other like dielectric material. The capacitor C and the 3D inductor L provide passive components (e.g., an inductor-capacitor (LC) portion of the RDL substrate 410) that may be interconnected to provide an RF filter as well as surface mount technology (SMT) matching passive components of the RF device 400. A performance of the inductor I may be improved with double-sided conductive pillars, according to aspects of the present disclosure.

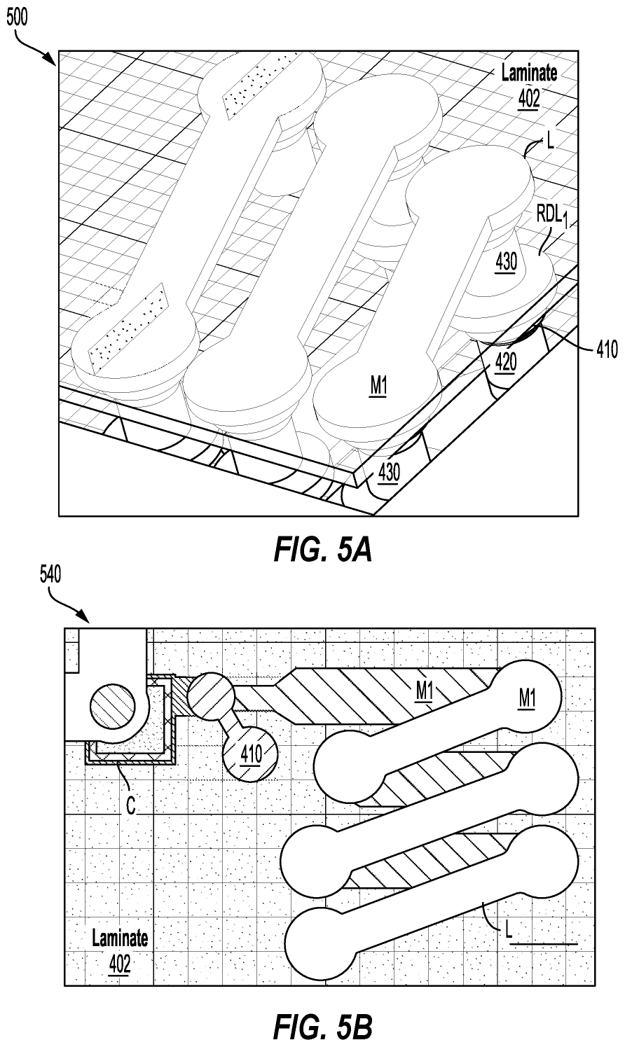

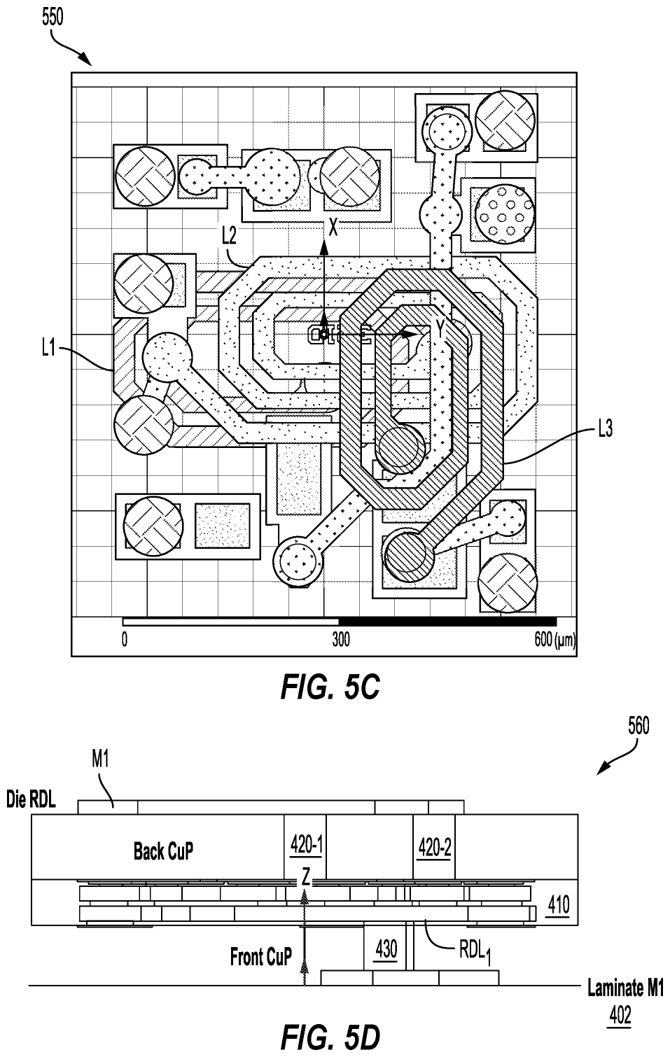

As shown in FIG. 4, the RF device 400 includes a first die 404 coupled to a first surface 414 of the RDL substrate 410, opposite a second surface 416 of the RDL substrate 410. In these aspects of the present disclosure, the first die 404 is coupled to the first surface 414 of the RDL substrate 410 by a first pair of conductive pillars 420 (420-1 and 420-2). Additionally, a laminate substrate 402 is coupled to the second surface 416 of the RDL substrate 410 by a second pair of conductive pillars 430 (430-1, 430-2). In some aspects of the present disclosure, a metallization layer M1 of the first die 404 couples the first pair of conductive pillars 420 (420-1 and 420-2) and a metallization layer M1 of the laminate substrate 402 couples to the second pair of conductive pillars 430 (430-1 and 430-2), which may improve a performance of the inductor I, as further illustrated in FIGS. 5A-5D.

FIGS. 5A-5B are schematic diagrams further illustrating the radio frequency (RF) device of FIG. 4, according to aspects of the present disclosure. FIG. 5A shows a perspective view of an RF device 500 further illustrating the 3D inductor L, according to aspects of the present disclosure. In this example, the 3D inductor L is shown in a multi-turn configuration, in which the turns of the inductor are formed from the metallization layer M1 of the laminate substrate 402 and the metallization layer M1 of the first die 404. Additionally, the second pair of conductive pillars 430 (430-1 and 430-2) couple the metallization layer M1 of the laminate substrate 402 to a first metallization layer M1 of the RDL₁ through the RDL substrate 410 to the first pair of conductive pillars 420 (420-1 and 420-2) and the metallization layer M1 of the first die 404.

FIG. 5B illustrates a top view 540 of the RF device 500 of FIG. 5A, according to aspects of the present disclosure. The top view 540 of the RF device 500 of FIG. 5A further illustrates the 3D inductor L in the multi-turn configuration, and coupled to the capacitor C through the M1 metallization layers of the first die 404. A portion of the RDL substrate 410 is also shown. The RF device 500 may implement a notch filter having a reduced notch frequency of 2.7 GHz and an improved rejection of approximately 35 decibels (dB). In this example, the inductor of the RF device 500 is a 2.5 turn inductor, having a significantly reduced size (e.g., 20%) relative to a conventional 3.5 turn inductor.

FIGS. 5C-5D are schematic diagrams further illustrating the radio frequency (RF) device 500 of FIGS. 5A-5B having planar inductors, according to further aspects of the present disclosure. FIG. 5C illustrates an RF device 550, including a first planar inductor L1 formed from a die RDL M1, as shown in a side view 560 of FIG. 5D. The RF device 550 also includes a second planar inductor L2 formed from an RDL₁ of the RDL substrate 410 and coupled to the first planar inductor L1 through the first pair of conductive pillars 420 (420-1 and 420-2), as shown in the side view 560 of FIG. 5D. Additionally, the RF device 550 includes a third planar inductor L3 formed from the metallization layer M1 of the laminate substrate 402 and coupled to the second planar inductor L2 through the second pair of conductive pillars 430 (430-1 and 430-2), as shown in the side view 560 of FIG. 5D. Beneficially, the first pair of conductive pillars 420 (420-1 and 420-2) and the second pair of conductive pillars 430 (430-1 and 430-2) enable formation of the first planar inductor L1, the second planar inductor L2, and the third planar inductor L3 in a reduced footprint (e.g., at 30% XY size reduction).

Referring again to FIG. 4, the addition of the first pair of conductive pillars 420 (420-1 and 420-2) and the second pair of conductive pillars 430 (430-1 and 430-2) improves a density of the 3D inductor L, which is approximately six (6) Nano-henrys (nH) per millimeter squared (6 nH/mm²). Additionally, the first pair of conductive pillars 420 (420-1 and 420-2) and the second pair of conductive pillars 430 (430-1 and 430-2) increase a length of an inductor loop 418, which improves an electrical performance of the 3D inductor L. In particular, a quality (Q)-factor of the 3D inductor L is greater than 90 at four gigahertz (e.g., 3D inductor L Q-factor>90 at 4 GHz (or 1.3 nH)) in the same XY footprint. An inductance of the 3D inductor L is approximately 1.2 nano-henrys per turn (e.g., inductance ˜1.2 nH/turn).

As described in further detail below, the RF device 400 exhibits improved thermal performance based on a backside path provided to the first die 404 using the double-sided conductive pillars, as well as the application of a molding compound to each set of pillars to provide a double molding. Additionally, a similar wafer cost is achieved when the first pair of conductive pillars are provided with the first die 404 during fabrication. Additionally, the first die 404 may be an active die, having MIM capacitors integrated in the first die 404 (e.g., without extra cost to the first die 404). In this configuration, the 3D inductor L is coupled through the conductive pillars 420 to the available MIM capacitors in the first die 404. In some aspects of the present disclosure, MIM capacitors from both passive and active dies can be combined with the 3D inductor L.

In some aspects of the present disclosure, the RDL substrate 410 is a double-sided substrate to enable integration of an RF filter, SMT passive component matching, and laminate routing/inductors. Benefits of the RDL substrate 410 include a significant (e.g., 2×) reduction in the size of the RF device 400 in an XY dimension. In addition, the RDL substrate 410 also enables a significant (e.g., 2×) Z height reduction. For example, a four layer (4L) laminate package substrate may have a thickness of 260 microns compared to a 50 micron thickness of the RDL substrate 410. Eliminating the laminate package substrate by using the RDL substrate 410 provides both a cost and size reduction of the RF device 400, while providing comparable performance with a side-by-side on laminate package substrate RFFE module configuration.

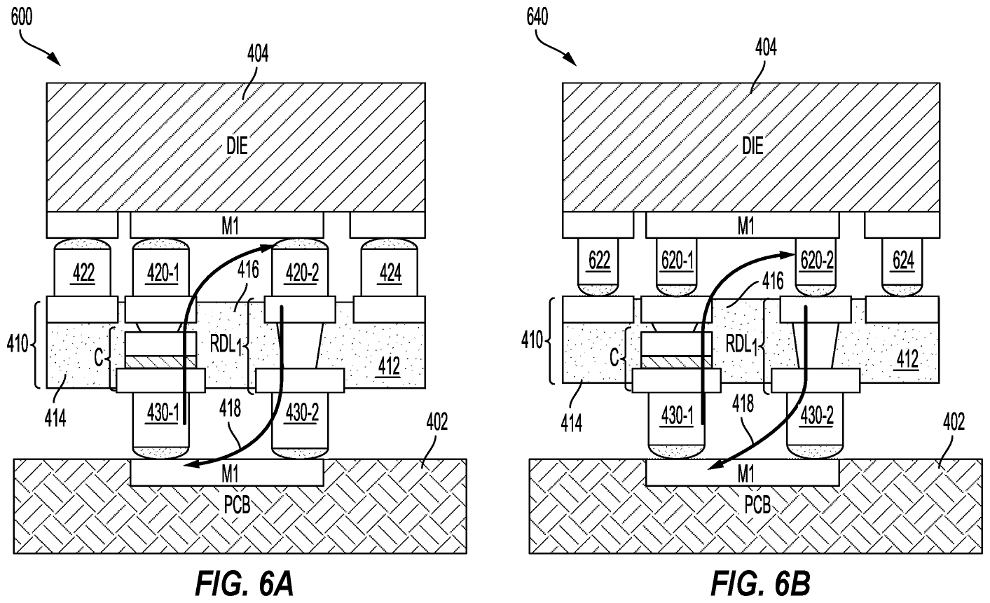

FIGS. 6A and 6B are block diagrams further illustrating the radio frequency (RF) device of FIG. 4, according to aspects of the present disclosure. As shown in FIG. 6A, an RF device 600 is similar to the RF device 400 of FIG. 4 and is described using similar reference numbers. As shown in FIG. 6A, however, the first die 404 is coupled to the second surface 416 of the RDL substrate 410 through the first pair of conductive pillars 420 (420-1 and 420-2) as well as a first conductive pillar 422 and a second conductive pillar 424. Additionally, the laminate substrate 402 (e.g., a printed circuit board (PCB)) is coupled to the first surface 414 of the RDL substrate 410 through the second pair of conductive pillars 430 (430-1 and 430-2). In FIG. 6B, an RF device 640 is configured similar to the RF device 600 in FIG. 6A, however, in FIG. 6B, the first die 404 is coupled to the second surface 416 of the RDL substrate 410 through a pair of die conductive pillars 620 (620-1 and 620-2) as well as a first die conductive pillar 622 and a second die conductive pillar 624. This configuration of the RF device 640 saves the cost of fabricating the first pair of conductive pillars 420 (420-1 and 420-2) as well as the first conductive pillar 422 and the second conductive pillar 424 of the RF device 600 of FIG. 6A.

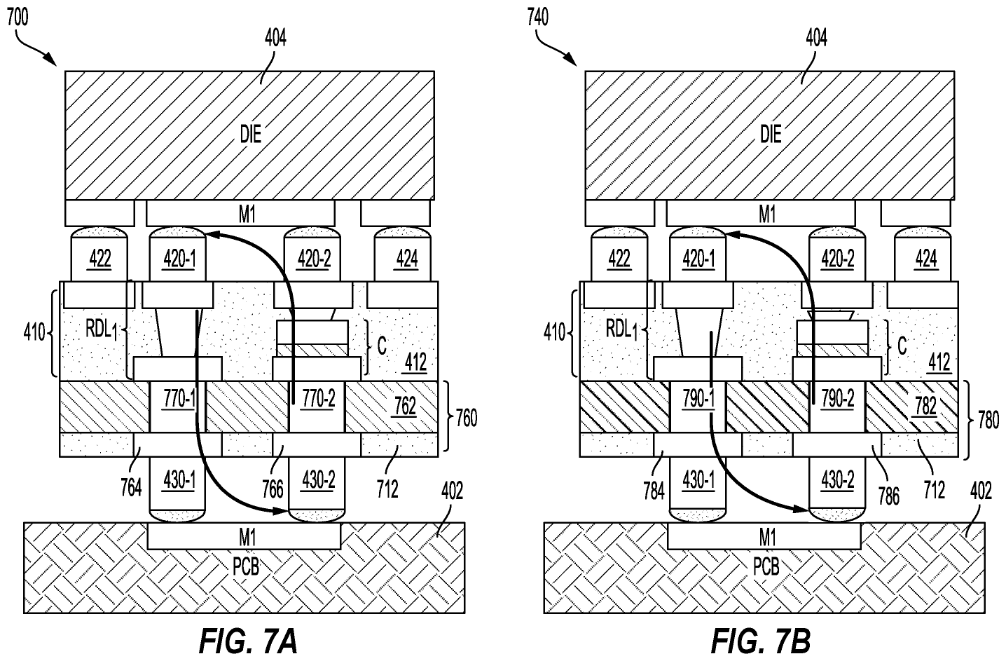

FIGS. 7A-7B are block diagrams illustrating various options to assemble a redistribution layer (RDL) substrate and a die to form radio frequency front-end (RFFE) modules, according to aspects of the present disclosure. As shown in FIG. 7A, an RF device 700 is similar to the RF device 600 of FIG. 6A and is described using similar reference numbers. As shown in FIG. 7A, however, a passive interposer 760 is coupled between the RDL substrate 410 and the second pair of conductive pillars 430 (430-1 and 430-2) by interposer vias. For example, the interposer vias may be implemented as through glass vias (TGVs) 770 (770-1, 770-2). In this example, the passive interposer 760 includes landing pads 764 and 766 in a dielectric layer 712 of the passive interposer 760. Additionally, the passive interposer 760 includes a glass core 762.

In FIG. 7B, an RF device 740 is configured similar to the RF device 700 in FIG. 7A, however, a passive interposer 780 is coupled between the RDL substrate 410 and the second pair of conductive pillars 430 (430-1 and 430-2) by interposer vias. For example, the interposer vias may be implemented as through mold vias (TMVs) 790 (790-1, 790-2). In this example, the passive interposer 780 also includes landing pads 784 and 786 in the dielectric layer 712 of the passive interposer 780. Additionally, the passive interposer 780 includes a mold compound core 782. In this configuration, the second pair of conductive pillars 430 (430-1 and 430-2) are coupled to the landing pads 764 and 766 with a metal-metal direct bonding or metal-metal or eutectic bonding.

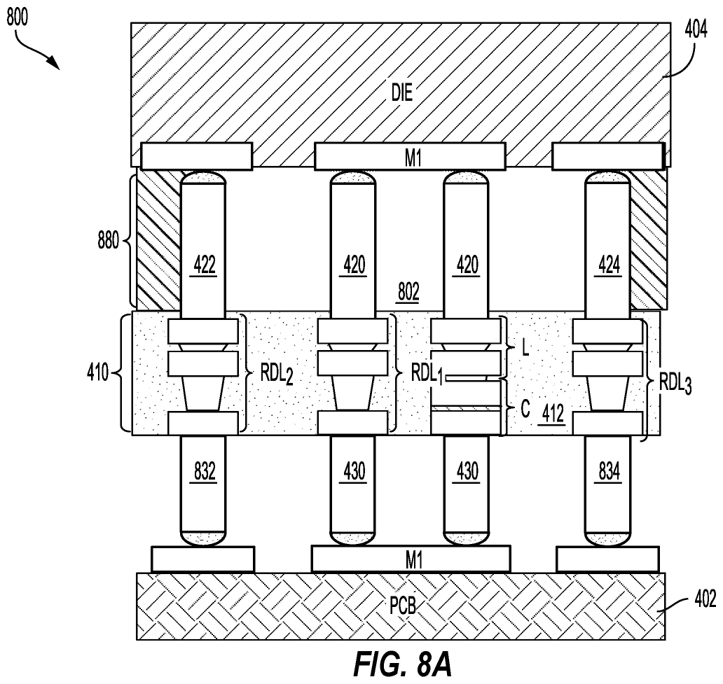

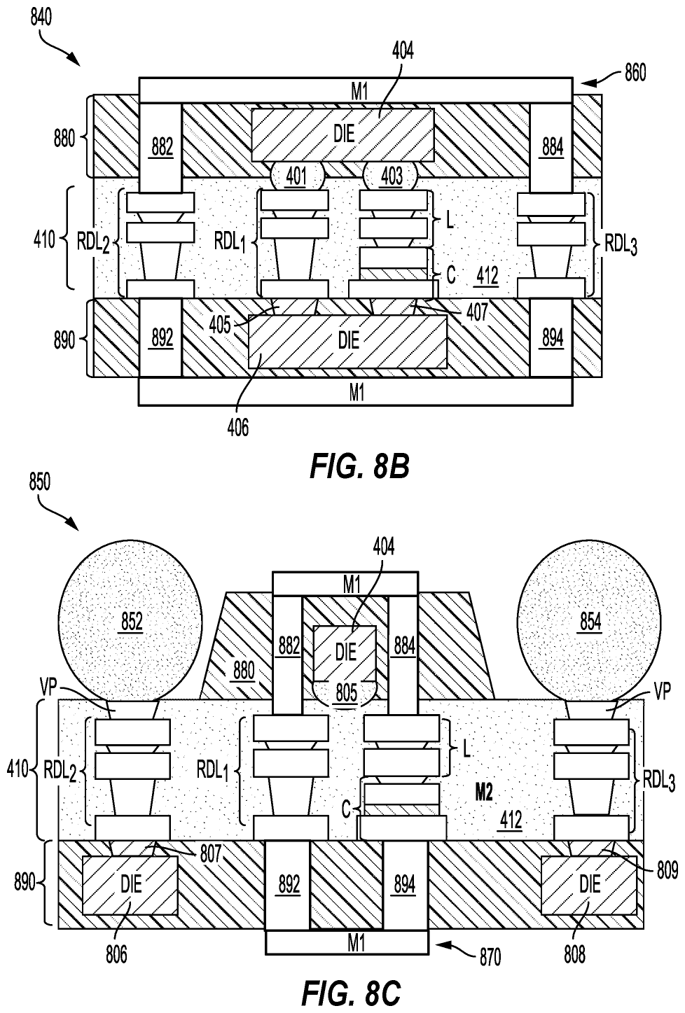

FIGS. 8A-8C are block diagrams further illustrating variations of the radio frequency (RF) device 400 of FIG. 4, according to aspects of the present disclosure. As shown in FIG. 8A, an RF device 800 is a variation of the RF device 600 of FIG. 6A and described using similar reference numbers. In some aspects of the present disclosure, a cavity 802 is provided between the RDL substrate 410 and the first die 404 by depositing a molding compound to seal outer sidewalls of the first conductive pillar 422 and the second conductive pillar 424. In this example, the first conductive pillar 422 and the second conductive pillar 424 are implemented as through mold vias (TMVs). In this example, the first conductive pillar 422 and the second conductive pillar 424 provide a fourth pair of conductive pillars.

As further illustrated in FIG. 8A, the RF device 800 includes a third conductive pillar 832 and a fourth conductive pillar 834 to further couple the RDL substrate 410 to the laminate substrate 402 (e.g., a printed circuit board (PCB)). In particular, the third conductive pillar 832 is coupled to the first conductive pillar 422 through a second RDL (RDL₂) for providing a first input/output (I/O) portion of the RF device 800. Additionally, the fourth conductive pillar 834 is coupled to the second conductive pillar 424 through a third RDL (RDL₃) for providing a second input/output (I/O) portion of the RF device 800. In this example, an inductor-capacitor (LC) portion of the RF device 800 is between the first I/O portion and the second I/O portion of the RF device 800. Additionally, the third conductive pillar 832 and a fourth conductive pillar 834 provide a third pair of conductive pillars.

As shown in FIG. 8B, an RF device 840 is illustrated in which an XY dimension of the RDL substrate 410 is greater than an XY dimension of the first die 404 and a second die 406. This configuration of the RDL substrate 410 is similar to the configuration shown in FIG. 8A, and is described using similar reference numbers. In this example, the first die 404 is encapsulated in a first molding compound (MC) layer 880 and coupled to the first RDL (RDL₁) and an LC portion of the RDL substrate 410 by package balls 401 and 403. Additionally, a second die 406 is encapsulated in a second MC layer 890 and coupled to the RDL₁ and the LC portion of the RDL substrate 410 by package balls 405 and 407. In this example, the package balls 401, 403, 405, and 407 may be formed by depositing tin (Sn) solder or reflowing tin silver (SnAg).

In some aspects of the present disclosure, the RF device 840 includes an outer-loop, dual pillar 3D inductor 860. In this example, the second RDL (RDL₂), and the third RDL (RDL₃) of the RDL substrate 410 couple together portions of the 3D inductor 860. In this arrangement, the 3D inductor 860 is composed of a first through mold via (TMV) 882 coupled to the RDL₂ and a second TMV 884 coupled to the RDL₃, and joined together through a first conductive trace M1 on a surface of the first MC layer 880. Additionally, the 3D inductor 860 is composed of a third TMV 892 coupled to the RDL₂ and a fourth TMV 894 coupled to the RDL₃, and joined together through a second conductive trace M1 on a surface of the second MC layer 890. As described, the first TMV 882 and the second TMV 884 may be referred to as a first pair of TMVs.

Additionally, the third TMV 892 and the fourth TMV 894 may be referred to as a second pair of TMVs.

FIG. 8C illustrates an RF device 850 in a multi-active die configuration, according to aspects of the present disclosure. This configuration of the RF device 850 is similar to the configuration shown in FIG. 8B, and is described using similar reference numbers. In this example, a first die 804 is encapsulated in the first molding compound (MC) layer 880 and coupled to the RDL substrate 410 through a package ball 805. Additionally, a second die 806 and a third die 808 are encapsulated in a second MC layer 890 and coupled to the first RDL (RDL₁) and the third RDL (RDL₃) by package balls 807 and 809. Package balls 852 and 854 are secured to via pads (VP) of the RDL₁ and the RDL₃, opposite the second die 806 and the third die 808, respectively.

In this example, the package balls 805, 807, 809, 852, and 854 may be formed by depositing tin (Sn) solder or reflowing tin silver (SnAg). In addition, the face of the RDL substrate 410, which includes package balls 852 and 854, may be part of a land grid array (LGA), a ball grid array (BGA), or other like interconnect structure.

In some aspects of the present disclosure, the RF device 850 includes an inner-loop, dual pillar 3D inductor 870. In this example, the RDL₁ and the LC portion of the RDL substrate 410 couple together portions of the 3D inductor 870. In this arrangement, the 3D inductor 870 is composed of the first through mold via (TMV) 882 coupled to the RDL₁ and the second TMV 884 coupled to the LC portion of the RDL substrate 410, and joined together through the first conductive trace M1 on the surface of the first molding compound (MC) layer 880. Additionally, the 3D inductor 870 is composed of a third TMV 892 coupled to the RDL₁ and a fourth TMV 894 coupled to the LC portion of the RDL substrate 410, and joined together through a second conductive trace M2 on the surface of the second MC layer 890.

In some aspects of the present disclosure, a functionality of the first die 404 of FIG. 4 is split between the first die 404 and the second die 406, as shown in FIG. 8B. As shown in FIG. 8C, the functionality of the first die 804 is split between the first die 804, the second die 806, and the third die 808. The first die 804, the second die 806, and the third die 808 may be implemented as a silicon (Si) or a III-V material active die. Alternatively, one of these dies may be implemented as a passive die or an acoustic die, although this configuration is less likely due to hermetic sealing specifications for acoustic/micro-electromechanical system (MEMS) devices. In some aspects of the present disclosure, the first die 804 provides an RF switch die, the second die 806 provides a low noise amplifier (LNA) die, and the third die 808 is implemented as a gallium arsenide (GaAs) die.

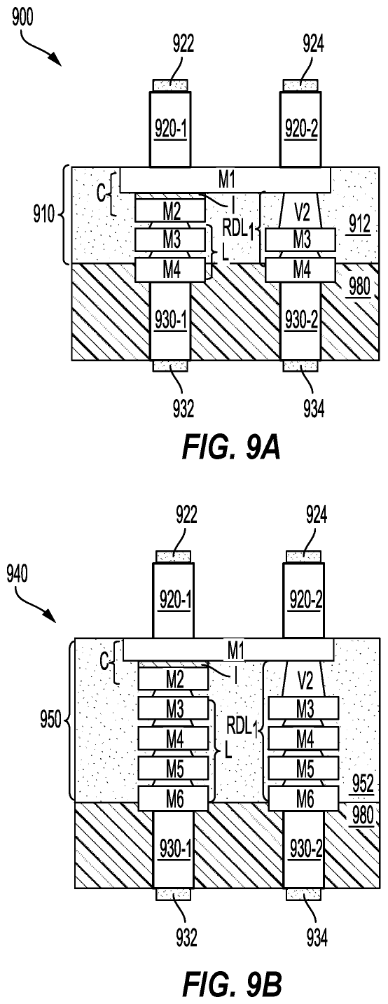

FIGS. 9A-9B are block diagrams illustrating a radio frequency (RF) device including a redistribution layer (RDL) substrate, according to aspects of the present disclosure. As shown in FIG. 9A, an RF device 900 includes a four layer (4L) RDL substrate 910 composed of interlayer dielectric (ILD) layers 912 formed of, for example, polyimide. In some aspects of the present disclosure, the ILD layers 912 include a metal-insulator-metal (MIM) capacitor C and a 3D inductor L formed from back-end-of-line (BEOL) metallization layers M1, M2, M3, and M4, which may include BEOL vias (e.g., V2, V3, and a via pad VP).

In these aspects of the present disclosure, a first pair of conductive pillars 920 (920-1 and 920-2) are coupled to a first metallization layer M1 of the RDL substrate 910. Conductive bumps 922 and 924 are secured to the first pair of conductive pillars 920 (920-1 and 920-2), which enable contacting, for example, the first die 404, as shown in FIG. 4. Alternatively, the conductive bumps 922 and 924 secured to the first pair of conductive pillars 920 (920-1 and 920-2) enable contacting of the laminate substrate 402, for example, as shown in FIG. 4. In this example, the conductive bumps 922 and 924 may be formed by depositing tin (Sn) solder or reflowing tin silver (SnAg) on the end of the first pair of conductive pillars 920 (920-1 and 920-2).

Additionally, a molding compound (MC) layer 980 is on an opposite surface of the RDL substrate 910, including a pair of through mold vias (TMVs) 930 (930-1, 930-2). In some aspects of the present disclosure, a fourth metallization layer M4 of the first RDL (RDL₁) and an LC portion of the RDL substrate 910 couples the pair of TMVs 930 (930-1 and 930-2). In this example, conductive bumps 932 and 934 are also secured to the pair of TMVs 930 (930-1 and 930-2), which enable contacting, for example, the first die 404, as shown in FIG. 4. Alternatively, the conductive bumps 932 and 934 secured to the pair of TMVs 930 (930-1 and 930-2) enable contacting the laminate substrate 402, for example, as shown in FIG. 4. In this example, the conductive bumps 932 and 934 are also formed by depositing tin (Sn) solder or reflowing tin silver (SnAg) on the end of the pair of TMVs 930 (930-1 and 930-2).

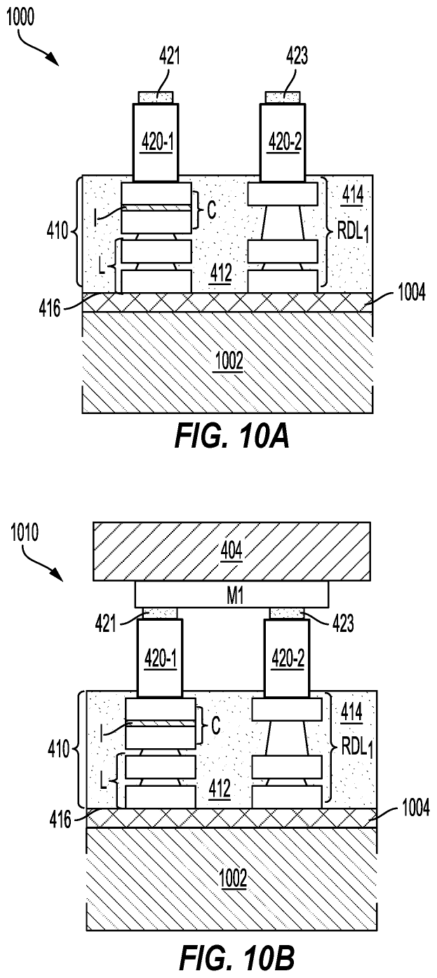

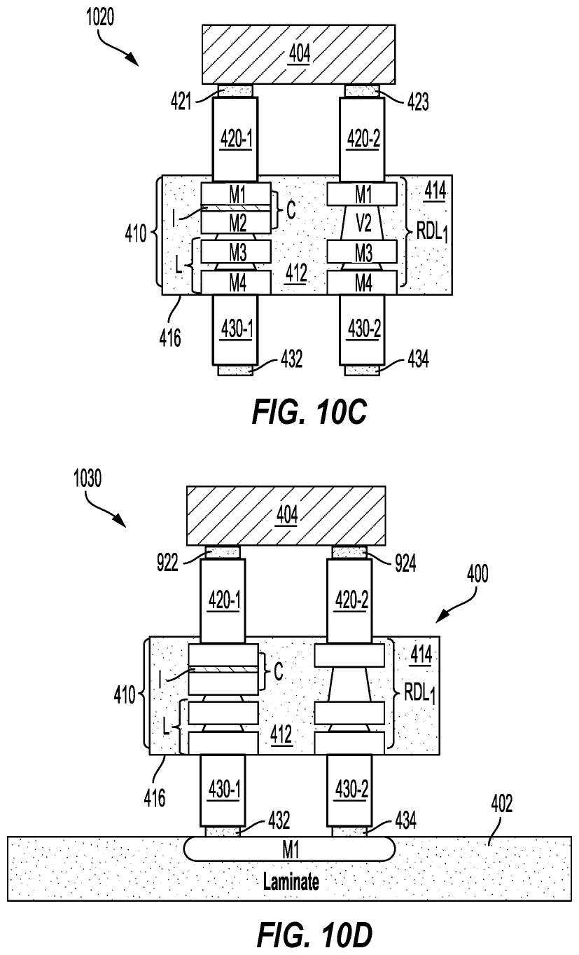

As shown in FIG. 9B, an RF device 940 is illustrated with a similar configuration as the RF device 900 shown in FIG. 9A, according to aspects of the present disclosure. The configuration of the RF device 940 is similar to the configuration shown in FIG. 9A, and is described using similar reference numbers. As shown in FIG. 9B, the RF device 940 includes a six layer (6L) RDL substrate 950 composed of interlayer dielectric (ILD) layers 952 formed of, for example, polyimide. In some aspects of the present disclosure, the ILD layers 952 include a metal-insulator-metal (MIM) capacitor C and a 3D inductor L formed from back-end-of-line (BEOL) metallization layers M1, M2, M3, M4, M5, and M6, which may include BEOL vias (e.g., V2, V3, V4, and VP). Although FIGS. 9A and 9B illustrate a 4L RDL substrate 910 and a 6L RDL substrate 950, respectively, it should be recognized that two layer (2L) to 6L RDL substrates are also contemplated according to aspects of the present disclosure. A process for fabrication of an RF device including an RDL substrate having double-sided conductive pillars is shown, for example, in FIGS. 10A-10D.

FIGS. 10A-10D are block diagrams illustrating a process of fabricating a radio frequency (RF) device including a redistribution layer (RDL) substrate having double-sided conductive pillars, according to aspects of the present disclosure. As shown in FIG. 10A, at step 1000, an RDL substrate 410 including at least one passive component (e.g., capacitor (C) and/or inductor (L)) in interlayer dielectric (ILD) layers 412 of the RDL substrate 410 is formed on a carrier glass substrate 1002.

Additionally, the first pair of conductive pillars 420 (420-1 and 420-2), including conductive bumps 421 and 423 are formed on the first metallization layer M1 of the first RDL (RDL₁) and the inductor-capacitor (LC) portion of the RDL substrate 410 near the first surface 414. In some aspects of the present disclosure, the carrier glass substrate 1002 is temporarily secured to the second surface 416 of the RDL substrate 410 with an adhesive layer 1004.

As shown in FIG. 10B, at step 1010, a metallization layer M1 of the first die 404 is coupled to the conductive bumps 421 and 423 of the first pair of conductive pillars 420 (420-1 and 420-2). As shown in FIG. 10C, at step 1020, the carrier glass substrate 1002 is removed from the surface of the RDL substrate 410. In some aspects of the present disclosure, the carrier glass substrate 1002 is removed from the RDL substrate 410 by exposing and illuminating the adhesive layer 1004 through the carrier glass substrate 1002. Additionally, the second pair of conductive pillars 430 (430-1 and 430-2), including the package bumps 432 and 434 are formed on the fourth metallization layer M4 of the RDL₁ and the LC portion of the RDL substrate 410.

As shown in FIG. 10D, at step 1030, a metallization layer M1 of the laminate substrate 402 is coupled to the package bumps 432 and 434 of the second pair of conductive pillars 430 (430-1 and 430-2). Attachment of the laminate substrate 402 to the RDL substrate 410 through the second pair of conductive pillars 430 (430-1 and 430-2) completes the formation of the RF device 400, for example, as shown in FIG. 4.

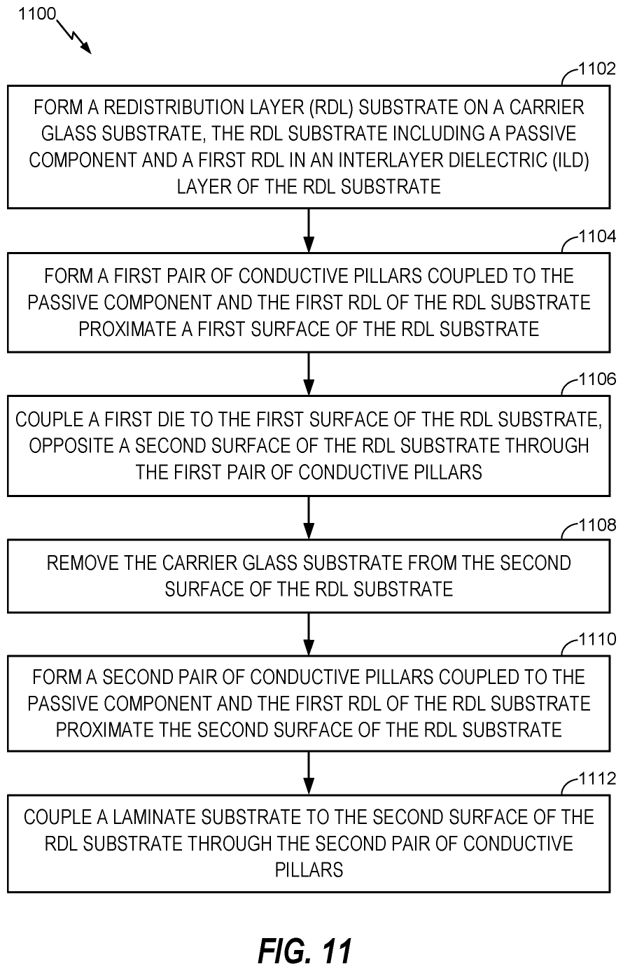

FIG. 11 is a process flow diagram illustrating a method for fabricating a radio frequency (RF) device including a redistribution layer (RDL) substrate having double-sided conductive pillars, according to aspects of the present disclosure. A method 1100 begins in block 1102, in which a redistribution layer (RDL) substrate is formed on a carrier glass substrate, in which the RDL substrate includes a passive component and a first RDL in an interlayer dielectric (ILD) layer of the RDL substrate. For example, as shown in FIG. 10A, at step 1000, the RDL substrate 410 is formed on a carrier glass substrate 1002. As shown in FIG. 4, the RDL substrate 410 is composed of the ILD layers 412 formed from, for example, polyimide. The ILD layers 412 include the MIM capacitor C and the 3D inductor L. The ILD layers 412 also include the first RDL (RDL₁) to complete the RDL substrate 410. In this example, the carrier glass substrate 1002 is temporarily secured to the RDL substrate 410 with an adhesive layer 1004. That is, the carrier glass substrate 1002 provides a wafer supporting system (WSS).

In block 1104, a first pair of conductive pillars are formed and coupled to the passive component and the first RDL of the RDL substrate proximate a first surface of the RDL substrate. For example, as shown in FIG. 10A, the first pair of conductive pillars 420 (420-1 and 420-2), including conductive bumps 421 and 423, are formed on the first metallization layer M1 of the RDL₁ and the LC portion of the RDL substrate 410 near the first surface 414. In some aspects of the present disclosure, the carrier glass substrate 1002 is temporarily secured to the RDL substrate 410 with an adhesive layer 1004.

Referring again to FIG. 11, at block 1106, a first die is coupled to the first surface of the RDL substrate, opposite a second surface of the RDL substrate, through the first pair of conductive pillars. For example, as shown in FIG. 10B, at step 1010, the metallization layer M1 of the first die 404 is coupled to the conductive bumps 421 and 423 of the first pair of conductive pillars 420 (420-1 and 420-2). In this example, the conductive bumps 421 and 423 secure the first die 404 to the RDL₁ and the LC portion of the RDL substrate 410 through the first pair of conductive pillars 420 (420-1 and 420-2).

At block 1108, the carrier glass substrate is removed from the second surface of the RDL substrate. For example, as shown in FIG. 10C, at step 1020, the carrier glass substrate 1002 is removed from the second surface of the RDL substrate 410. The carrier glass substrate 1002 may be removed from the RDL substrate 410 by exposing and illuminating the adhesive layer 1004 through the carrier glass substrate 1002. At block 1110, a second pair of conductive pillars are formed and coupled to the passive component and the first surface of the RDL substrate proximate the second surface of the RDL substrate. For example, as shown in FIG. 10C, at step 1020, the second pair of conductive pillars 430 (430-1 and 430-2), including the package bumps 432 and 434, are formed on the fourth metallization layer M4 of the RDL₁ and the LC portion of the RDL substrate 410.

At block 1112, a laminate substrate is coupled to the second surface of the RDL substrate through the second pair of conductive pillars. For example, as shown in

FIG. 10D, at step 1030, a metallization layer M1 of the laminate substrate 402 is coupled to the package bumps 432 and 434 of the second pair of conductive pillars 430 (430-1 and 430-2). Attachment of the laminate substrate 402 to the RDL substrate 410 through the second pair of conductive pillars 430 (430-1 and 430-2) completes the formation of the RF device 400, for example, as shown in FIG. 4.

In some aspects of the present disclosure, a redistribution layer (RDL) substrate provides a double-sided substrate to enable integration of a radio frequency (RF) filter, surface-mount technology (SMT) passive component matching, and laminate routing/inductors. Benefits of the RDL substrate include a significant (e.g., 2×) reduction in the size of the RF device in an XY dimension. In addition, the RDL substrate also enables a significant (e.g., 2×) Z height reduction. For example, a four layer (4L) laminate package substrate may have a thickness of 260 microns compared to a 50 micron thickness of the RDL substrate 410. Eliminating the laminate package substrate by using the RDL substrate provides both a cost and size reduction of the RF device 400, while providing comparable performance with a side-by-side on laminate package substrate RF front-end (RFFE) module configuration.

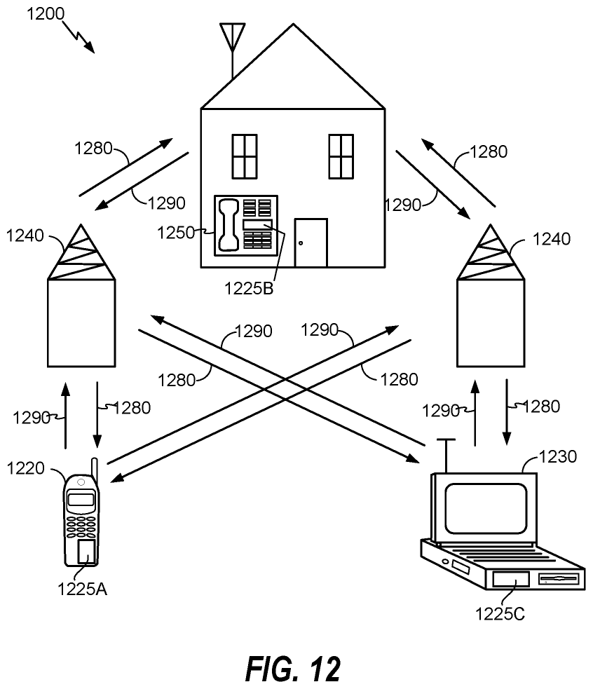

FIG. 12 is a block diagram showing an exemplary wireless communications system 1200 in which an aspect of the disclosure may be advantageously employed. For purposes of illustration, FIG. 12 shows three remote units 1220, 1230, and 1250 and two base stations 1240. It will be recognized that wireless communications systems may have many more remote units and base stations. Remote units 1220, 1230, and 1250 include integrated circuit (IC) devices 1225A, 1225C, and 1225B that include the disclosed RDL substrate. It will be recognized that other devices may also include the disclosed RDL substrate, such as the base stations, switching devices, and network equipment. FIG. 12 shows forward link signals 1280 from the base station 1240 to the remote units 1220, 1230, and 1250, and reverse link signals 1290 from the remote units 1220, 1230, and 1250 to the base stations 1240.

In FIG. 12, remote unit 1220 is shown as a mobile telephone, remote unit 1230 is shown as a portable computer, and remote unit 1250 is shown as a fixed location remote unit in a wireless local loop system. For example, the remote units may be a mobile phone, a hand-held personal communication systems (PCS) unit, a portable data unit, such as a personal data assistant, a GPS enabled device, a navigation device, a set top box, a music player, a video player, an entertainment unit, a fixed location data unit, such as meter reading equipment, or other device that stores or retrieves data or computer instructions, or combinations thereof. Although FIG. 12 illustrates remote units according to the aspects of the present disclosure, the present disclosure is not limited to these exemplary illustrated units. Aspects of the present disclosure may be suitably employed in many devices, which include the disclosed RDL substrate.

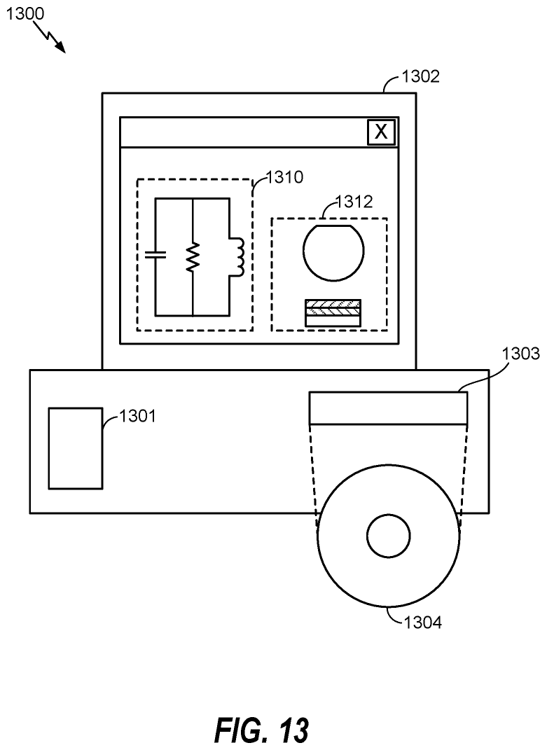

FIG. 13 is a block diagram illustrating a design workstation used for circuit, layout, and logic design of a semiconductor component, such as the RDL substrate disclosed above. A design workstation 1300 includes a hard disk 1301 containing operating system software, support files, and design software such as Cadence or OrCAD. The design workstation 1300 also includes a display 1302 to facilitate design of a circuit 1310 or a radio frequency (RF) component 1312 such as an RDL substrate. A storage medium 1304 is provided for tangibly storing the design of the circuit 1310 or the RF component 1312 (e.g., the RDL substrate). The design of the circuit 1310 or the RF component 1312 may be stored on the storage medium 1304 in a file format such as GDSII or GERBER. The storage medium 1304 may be a compact disc read-only memory (CD-ROM), digital versatile disc (DVD), hard disk, flash memory, or other appropriate device. Furthermore, the design workstation 1300 includes a drive apparatus 1303 for accepting input from or writing output to the storage medium 1304.

Data recorded on the storage medium 1304 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1304 facilitates the design of the circuit 1310 or the RF component 1312 by decreasing the number of processes for designing semiconductor wafers.

Implementation examples are described in the following numbered clauses:
1. A device, comprising:
a redistribution layer (RDL) substrate;
a passive component in the RDL substrate proximate a first surface of the RDL substrate;
a first die coupled to a second surface of the RDL substrate, opposite the first surface of the RDL substrate, through at least a first pair of conductive pillars; and
a laminate substrate coupled to the first surface of the RDL substrate through at least a second pair of conductive pillars.
2. The device of clause 1, further comprising:
an interposer on the first surface of the RDL substrate; and
a pair of through interposer vias coupled to the second pair of conductive pillars.
3. The device of clause 2, in which the interposer is composed of glass, and the pair of through interposer vias comprise through glass vias (TGVs).
4. The device of clause 2, in which the interposer is composed of a molding compound, and the pair of through interposer vias comprise through mold vias (TMVs).
5. The device of any of clauses 1-4, in which the laminate substrate comprises a printed circuit board having a metallization layer to couple to the second pair of conductive pillars.
6. The device of any of clauses 1-5, in which the first die comprises a metallization layer on a surface of the first die to couple to the first pair of conductive pillars.
7. The device of any of clauses 1-6, further comprising:
a first RDL in the RDL substrate;
a second RDL in the RDL substrate;
a third pair of conductive pillars coupled to the first RDL and the second RDL proximate the first surface of the RDL substrate;
a fourth pair of conductive pillars coupled to the first RDL and the second RDL proximate the second surface of the RDL substrate; and
a molding compound on outer sidewalls of the fourth pair of conductive pillars to seal a cavity between the RDL substrate and the first die.
8. The device of any of clauses 1-7, in which the passive component comprises a metal-insulator-metal (MIM) capacitor and a 3D inductor coupled to the MIM capacitor.
9. The device of any of clauses 1-7, in which the passive component comprises a metal-insulator-metal (MIM) capacitor and 2D inductors coupled to the MIM capacitor.
10. The device of any of clauses 1-9, in which the RDL substrate comprises a radio frequency (RF) filter, integrated in a radio frequency front-end (RFFE) module.
11. A method for fabricating a radio frequency (RF) device, comprising:
forming a redistribution layer (RDL) substrate on a carrier glass substrate, the RDL substrate including a passive component and a first RDL in an interlayer dielectric (ILD) layer of the RDL substrate;
forming a first pair of conductive pillars coupled to the passive component and the first RDL of the RDL substrate proximate a first surface of the RDL substrate;
coupling a first die to the first surface of the RDL substrate, opposite a second surface of the RDL substrate, through the first pair of conductive pillars; removing the carrier glass substrate from the second surface of the RDL substrate;
forming a second pair of conductive pillars coupled to the passive component and the first RDL of the RDL substrate proximate the second surface of the RDL substrate; and
coupling a laminate substrate to the second surface of the RDL substrate through the second pair of conductive pillars.
12. The method of clause 11, further comprising:
coupling an interposer on the second surface of the RDL substrate; and
forming a pair of through interposer vias coupled to the second pair of conductive pillars.
13. The method of clause 12, in which the interposer is composed of glass, and the pair of through interposer vias comprise through glass vias (TGVs).
14. The method of clause 12, in which the interposer is composed of a molding compound, and the pair of through interposer vias comprise through mold vias (TMVs).
15. The method of any of clauses 11-14, in which the laminate substrate comprises a printed circuit board having a metallization layer to couple to the second pair of conductive pillars.
16. The method of any of clauses 11-15, in which the first die comprises a metallization layer on a surface of the first die to couple to the first pair of conductive pillars.
17. The method of any of clauses 11-16, further comprising:
forming a second RDL in the RDL substrate;
forming a third RDL in the RDL substrate;
forming a third pair of conductive pillars coupled to the third RDL and the second RDL proximate the first surface of the RDL substrate;
forming a fourth pair of conductive pillars coupled to the third RDL and the second RDL proximate the second surface of the RDL substrate; and
depositing a molding compound on outer sidewalls of the third pair of conductive pillars to seal a cavity between the RDL substrate and the first die.
18. The method of any of clauses 11-17, in which the passive component comprises a metal-insulator-metal (MIM) capacitor and a 3D inductor coupled to the MIM capacitor.
19. The method of any of clauses 11-17, in which the passive component comprises a metal-insulator-metal (MIM) capacitor and 2D inductors coupled to the MIM capacitor.
20. The method of any of clauses 11-19, in which the RDL substrate comprises a radio frequency (RF) filter, integrated in a radio frequency front-end (RFFE) module.
21. A device, comprising:

a redistribution layer (RDL) substrate, including a passive component and a first RDL in an interlayer dielectric (ILD) layer of the RDL substrate;
coupling a first die to a first surface of the RDL substrate, opposite a second surface of the RDL substrate;
depositing a first molding compound (MC) layer on the first surface of the RDL substrate and the first die;
a second die coupled to the first RDL of the RDL substrate proximate the second surface of the RDL substrate; and
a second MC layer on the second surface of the RDL substrate and the second die.
22. The device of clause 21, further comprising:
a second RDL in the RDL substrate;
a third RDL in the RDL substrate;
a first pair of through mold vias (TMVs) coupled to the second RDL and the third RDL through the first MC layer;
a second pair of TMVs coupled to the second RDL and the third RDL through the second MC layer; and
a 3D inductor comprising a first conductive trace on a surface of the first MC layer coupled to the first pair of TMVs, and a second conductive trace on a surface of the second MC layer coupled to the second pair of TMVs.
23. The device of clause 21, further comprising:
a second RDL in the RDL substrate;
a third RDL in the RDL substrate;
a third die coupled to the third RDL proximate the second surface of the RDL substrate;
a first pair of through mold vias (TMVs) coupled to the second RDL and the passive component through the first MC layer;
a second pair of TMVs coupled to the second RDL and the passive component through the second MC layer; and
a 3D inductor comprising a first conductive trace on a surface of the first MC layer coupled to the first pair of TMVs, and a second conductive trace on a surface of the second MC layer coupled to the second pair of TMVs.
24. The device of any of clauses 21-23, in which the passive component comprises a metal-insulator-metal (MIM) capacitor and a 3D inductor coupled to the MIM capacitor.
25. The device of any of clauses 21-24, in which the RDL substrate comprises a radio frequency (RF) filter, integrated in a radio frequency front-end (RFFE) module.
26. A method for fabricating a radio frequency (RF) device, comprising:
forming a redistribution layer (RDL) substrate on a carrier glass substrate, the RDL substrate including a passive component and a first RDL in an interlayer dielectric (ILD) layer of the RDL substrate;
coupling a first die to a first surface of the RDL substrate, opposite a second surface of the RDL substrate;
depositing a first molding compound (MC) layer on the first surface of the RDL substrate and the first die; removing the carrier glass substrate from the second surface of the RDL substrate;
coupling a second die to the first RDL of the RDL substrate proximate the second surface of the RDL substrate; and
depositing a second MC layer on the second surface of the RDL substrate and the second die.
27. The method of clause 26, further comprising:
forming a second RDL in the RDL substrate;
forming a third RDL in the RDL substrate;
forming a first pair of through mold vias (TMVs) coupled to the second RDL and the third RDL through the first MC layer;
forming a second pair of TMVs coupled to the second RDL and the third RDL through the second MC layer; and
forming a 3D inductor comprising a first conductive trace on a surface of the first MC layer coupled to the first pair of TMVs, and a second conductive trace on a surface of the second MC layer coupled to the second pair of TMVs.
28. The method of clause 26, further comprising:
forming a second RDL in the RDL substrate;
forming a third RDL in the RDL substrate;
coupling a third die to the third RDL proximate the second surface of the RDL substrate;
forming a first pair of through mold vias (TMVs) coupled to the second RDL and the passive component through the first MC layer;
forming a second pair of TMVs coupled to the second RDL and the passive component through the second MC layer; and forming a 3D inductor comprising a first conductive trace on a surface of the first MC layer coupled to the first pair of TMVs, and a second conductive trace on a surface of the second MC layer coupled to the second pair of TMVs.
29. The method of any of clauses 26-28, in which the passive component comprises a metal-insulator-metal (MIM) capacitor and a 3D inductor coupled to the MIM capacitor.
30. The method of any of clauses 26-29, in which the RDL substrate comprises a radio frequency (RF) filter, integrated in a radio frequency front-end (RFFE) module.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include random access memory (RAM), read-only memory (ROM), electrically erasable programmable read-only memory (EEPROM), compact disc read-only memory (CD-ROM) or other optical disk storage, magnetic disk storage or other magnetic storage devices, or other medium that can be used to store desired program code in the form of instructions or data structures and that can be accessed by a computer. Disk and disc, as used herein, include compact disc (CD), laser disc, optical disc, digital versatile disc (DVD), floppy disk and Blu-ray® disc, where disks usually reproduce data magnetically, while discs reproduce data optically with lasers.

Combinations of the above should also be included within the scope of computer-readable media.

In addition to storage on computer-readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions, and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, composition of matter, means, methods, and steps described in the specification. As one of ordinary skill in the art will readily appreciate from the disclosure, processes, machines, manufacture, compositions of matter, means, methods, or steps, presently existing or later to be developed that perform substantially the same function, or achieve substantially the same result as the corresponding configurations described herein, may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application-specific integrated circuit (ASIC), a field-programmable gate array (FPGA) or other programmable logic device, discrete gate or transistor logic, discrete hardware components, or any combination thereof designed to perform the functions described herein. A general-purpose processor may be a microprocessor, but, in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the present disclosure may be embodied directly in hardware, in a software module executed by a processor, or in a combination of the two. A software module may reside in random access memory (RAM), flash memory, read-only memory (ROM), erasable programmable read-only memory (EPROM), electrically erasable programmable read-only memory (EEPROM), registers, hard disk, a removable disk, a compact disc read-only memory (CD-ROM), or any other form of storage medium known in the art. An exemplary storage medium is coupled to the processor such that the processor can read information from, and write information to, the storage medium. In the alternative, the storage medium may be integral to the processor. The processor and the storage medium may reside in an application-specific integrated circuit (ASIC). The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general-purpose or special-purpose computer. By way of example, and not limitation, such computer-readable media can include random access memory (RAM), read-only memory (ROM), electrically erasable programmable read-only memory (EEPROM), compact disc read-only memory (CD-ROM) or other optical disk storage, magnetic disk storage or other magnetic storage devices, or any other medium that can be used to carry or store specified program code means in the form of instructions or data structures and that can be accessed by a general-purpose or special-purpose computer, or a general-purpose or special-purpose processor. In addition, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include compact disc (CD), laser disc, optical disc, digital versatile disc (DVD), floppy disk, and Blu-ray® disc, where disks usually reproduce data magnetically, while discs reproduce data optically with lasers. Combinations of the above should also be included within the scope of computer-readable media.

The previous description of the present disclosure is provided to enable any person skilled in the art to make or use the disclosure. Various modifications to the present disclosure will be readily apparent to those skilled in the art, and the generic principles defined herein may be applied to other variations without departing from the spirit or scope of the disclosure. Thus, the present disclosure is not intended to be limited to the examples and designs described herein but is to be accorded the widest scope consistent with the principles and novel features disclosed herein.

What is claimed is:

1. A device, comprising:
a redistribution layer (RDL) substrate;
a passive component in the RDL substrate proximate a first surface of the RDL substrate;
a first die coupled to a second surface of the RDL substrate, opposite the first surface of the RDL substrate, through at least a first pair of conductive pillars; and
a laminate substrate coupled to the first surface of the RDL substrate through at least a second pair of conductive pillars.

2. The device of claim 1, further comprising:
an interposer on the first surface of the RDL substrate; and
a pair of through interposer vias coupled to the second pair of conductive pillars.

3. The device of claim 2, in which the interposer is composed of glass, and the pair of through interposer vias comprise through glass vias (TGVs).

4. The device of claim 2, in which the interposer is composed of a molding compound, and the pair of through interposer vias comprise through mold vias (TMVs).

5. The device of claim 1, in which the laminate substrate comprises a printed circuit board having a metallization layer to couple to the second pair of conductive pillars.

6. The device of claim 1, in which the first die comprises a metallization layer on a surface of the first die to couple to the first pair of conductive pillars.

7. The device of claim 1, further comprising:
a first RDL in the RDL substrate;
a second RDL in the RDL substrate;
a third pair of conductive pillars coupled to the first RDL and the second RDL proximate the first surface of the RDL substrate;
a fourth pair of conductive pillars coupled to the first RDL and the second RDL proximate the second surface of the RDL substrate; and
a molding compound on outer sidewalls of the fourth pair of conductive pillars to seal a cavity between the RDL substrate and the first die.

8. The device of claim 1, in which the passive component comprises a metal-insulator-metal (MIM) capacitor and a 3D inductor coupled to the MIM capacitor.

9. The device of claim 1, in which the passive component comprises a metal-insulator-metal (MIM) capacitor and 2D inductors coupled to the MIM capacitor.

10. The device of claim 1, in which the RDL substrate comprises a radio frequency (RF) filter, integrated in a radio frequency front-end (RFFE) module.

11. A method for fabricating a radio frequency (RF) device, comprising:
forming a redistribution layer (RDL) substrate on a carrier glass substrate, the RDL substrate including a passive component and a first RDL in an interlayer dielectric (ILD) layer of the RDL substrate;
forming a first pair of conductive pillars coupled to the passive component and the first RDL of the RDL substrate proximate a first surface of the RDL substrate;
coupling a first die to the first surface of the RDL substrate, opposite a second surface of the RDL substrate, through the first pair of conductive pillars;
removing the carrier glass substrate from the second surface of the RDL substrate;
forming a second pair of conductive pillars coupled to the passive component and the first RDL of the RDL substrate proximate the second surface of the RDL substrate; and
coupling a laminate substrate to the second surface of the RDL substrate through the second pair of conductive pillars.

12. The method of claim 11, further comprising:
coupling an interposer on the second surface of the RDL substrate; and
forming a pair of through interposer vias coupled to the second pair of conductive pillars.

13. The method of claim 12, in which the interposer is composed of glass, and the pair of through interposer vias comprise through glass vias (TGVs).

14. The method of claim 12, in which the interposer is composed of a molding compound, and the pair of through interposer vias comprise through mold vias (TMVs).

15. The method of claim 11, in which the laminate substrate comprises a printed circuit board having a metallization layer to couple to the second pair of conductive pillars.

16. The method of claim 11, in which the first die comprises a metallization layer on a surface of the first die to couple to the first pair of conductive pillars.

17. The method of claim 11, further comprising:
forming a second RDL in the RDL substrate;
forming a third RDL in the RDL substrate;
forming a third pair of conductive pillars coupled to the third RDL and the second RDL proximate the first surface of the RDL substrate;
forming a fourth pair of conductive pillars coupled to the third RDL and the second RDL proximate the second surface of the RDL substrate; and
depositing a molding compound on outer sidewalls of the third pair of conductive pillars to seal a cavity between the RDL substrate and the first die.

18. The method of claim 11, in which the passive component comprises a metal-insulator-metal (MIM) capacitor and a 3D inductor coupled to the MIM capacitor.

19. The method of claim 11, in which the passive component comprises a metal-insulator-metal (MIM) capacitor and 2D inductors coupled to the MIM capacitor.

20. The method of claim 11, in which the RDL substrate comprises a radio frequency (RF) filter, integrated in a radio frequency front-end (RFFE) module.

21. A device, comprising:
a redistribution layer (RDL) substrate, including a passive component and a first RDL in an interlayer dielectric (ILD) layer of the RDL substrate;
a first die coupled to a first surface of the RDL substrate, opposite a second surface of the RDL substrate;
a first molding compound (MC) layer on the first surface of the RDL substrate and the first die;
a second die coupled to the first RDL of the RDL substrate proximate the second surface of the RDL substrate; and
a second MC layer on the second surface of the RDL substrate and the second die.

22. The device of claim 21, further comprising:
a second RDL in the RDL substrate;
a third RDL in the RDL substrate;
a first pair of through mold vias (TMVs) coupled to the second RDL and the third RDL through the first MC layer;
a second pair of TMVs coupled to the second RDL and the third RDL through the second MC layer; and
a 3D inductor comprising a first conductive trace on a surface of the first MC layer coupled to the first pair of TMVs, and a second conductive trace on a surface of the second MC layer coupled to the second pair of TMVs.

23. The device of claim 21, further comprising:
a second RDL in the RDL substrate;
a third RDL in the RDL substrate;
a third die coupled to the third RDL proximate the second surface of the RDL substrate;
a first pair of through mold vias (TMVs) coupled to the second RDL and the passive component through the first MC layer;
a second pair of TMVs coupled to the second RDL and the passive component through the second MC layer; and
a 3D inductor comprising a first conductive trace on a surface of the first MC layer coupled to the first pair of TMVs, and a second conductive trace on a surface of the second MC layer coupled to the second pair of TMVs.

24. The device of claim 21, in which the passive component comprises a metal-insulator-metal (MIM) capacitor and a 3D inductor coupled to the MIM capacitor.

25. The device of claim 21, in which the RDL substrate comprises a radio frequency (RF) filter, integrated in a radio frequency front-end (RFFE) module.

26. A method for fabricating a radio frequency (RF) device, comprising:
forming a redistribution layer (RDL) substrate on a carrier glass substrate, the RDL substrate including a passive component and a first RDL in an interlayer dielectric (ILD) layer of the RDL substrate;
coupling a first die to a first surface of the RDL substrate, opposite a second surface of the RDL substrate;
depositing a first molding compound (MC) layer on the first surface of the RDL substrate and the first die;
removing the carrier glass substrate from the second surface of the RDL substrate;
coupling a second die to the first RDL of the RDL substrate proximate the second surface of the RDL substrate; and
depositing a second MC layer on the second surface of the RDL substrate and the second die.

27. The method of claim 26, further comprising:
forming a second RDL in the RDL substrate;
forming a third RDL in the RDL substrate;
forming a first pair of through mold vias (TMVs) coupled to the second RDL and the third RDL through the first MC layer;
forming a second pair of TMVs coupled to the second RDL and the third RDL through the second MC layer; and
forming a 3D inductor comprising a first conductive trace on a surface of the first MC layer coupled to the first pair of TMVs, and a second conductive trace on a surface of the second MC layer coupled to the second pair of TMVs.

28. The method of claim 26, further comprising:
forming a second RDL in the RDL substrate;
forming a third RDL in the RDL substrate;
coupling a third die to the third RDL proximate the second surface of the RDL substrate;
forming a first pair of through mold vias (TMVs) coupled to the second RDL and the passive component through the first MC layer;
forming a second pair of TMVs coupled to the second RDL and the passive component through the second MC layer; and
forming a 3D inductor comprising a first conductive trace on a surface of the first MC layer coupled to the first pair of TMVs, and a second conductive trace on a surface of the second MC layer coupled to the second pair of TMVs.

29. The method of claim 26, in which the passive component comprises a metal-insulator-metal (MIM) capacitor and a 3D inductor coupled to the MIM capacitor.

30. The method of claim 26, in which the RDL substrate comprises a radio frequency (RF) filter, integrated in a radio frequency front-end (RFFE) module.
